(19) United States
(12) Patent Application Publication
(10) Pub. No.: US 2025/0159912 A1
(43) Pub. Date: May 15, 2025

(54) APPARATUS INCLUDING BOTTOM ELECTRODES COMPRISING OXYGEN-DOPED TITANIUM NITRIDE MATERIALS AND RELATED ELECTRONIC DEVICES AND METHODS OF FORMING THE ELECTRONIC DEVICES

(71) Applicant: Micron Technology, Inc., Boise, ID (US)

(72) Inventors: Dojun Kim, Boise, ID (US); Sanket S. Kelkar, Sunnyvale, CA (US); An-Jen B. Cheng, Boise, ID (US); Christopher W. Petz, Boise, ID (US); Ryan J. Waskiewicz, Boise, ID (US); Michael Mutch, Chardon, OH (US); Ashwin Panday, Boise, ID (US); Sarah bull, Boise, ID (US)

(21) Appl. No.: 18/909,685

(22) Filed: Oct. 8, 2024

Related U.S. Application Data
(60) Provisional application No. 63/597,446, filed on Nov. 9, 2023.

(51) Int. Cl. H10D 1/00; H10D 1/68

(52) U.S. Cl. CPC H10D 1/042; H10D 1/716

(57) ABSTRACT

An apparatus comprising one or more capacitors that comprise a bottom electrode, a high-k dielectric material, and a top electrode. The bottom electrode comprises an oxygen-doped titanium nitride material and one or more undoped titanium nitride materials. The oxygen-doped titanium nitride material is on sidewalls of the one or more undoped titanium nitride materials and the one or more undoped titanium nitride materials extending between sidewalls of the oxygen-doped titanium nitride material. Electronic devices and methods of forming an electronic device are also disclosed.

### CROSS-REFERENCE TO RELATED APPLICATION

This application claims the benefit under 35 U.S.C. § 119 (e) of U.S. Provisional Patent Application Ser. No. 63/597,446, filed Nov. 9, 2023, the disclosure of which is hereby incorporated herein in its entirety by this reference.

### TECHNICAL FIELD

Embodiments disclosed herein relate to the field of electronic device design and fabrication. More particularly, embodiments of the disclosure relate to electronic devices including capacitors having doped bottom electrode materials and related methods of forming the electronic devices.

### BACKGROUND

Electronic device designers desire to increase the level of integration or density of features within an electronic device by reducing dimensions of individual features and by reducing a separation distance between neighboring features. In addition, electronic device designers often desire to design architectures that are not only compact, but offer performance advantages, as well as simplified designs. A relatively common electronic device is a memory device. A memory device may include a memory array having a number of memory cells arranged in a grid pattern. One type of memory cell is a dynamic random access memory (DRAM) device, which is a volatile memory device that may lose a stored state over time unless the DRAM device is periodically refreshed by an external power supply. In one design configuration, a DRAM cell includes one access device (e.g., a transistor) and one storage device (e.g., a capacitor). DRAM utilizes capacitors (e.g., DRAM capacitors) to store an amount of electrical charge that represents the logical value of a stored bit. Modern applications of DRAM devices include large numbers of DRAM unit cells, arranged in an array of rows and columns. The DRAM cells are electrically accessible through digit lines and access lines (e.g., word lines) arranged along the rows and columns of the array. To increase integration density, a lateral footprint of the capacitors has been reduced by increasing the aspect ratio (i.e., ratio of height to width (e.g., diameter)) and decreasing the proximity of adjacent capacitors to one another.

Titanium nitride (TiN) is used as a bottom electrode material in the capacitor due to its good step coverage and interfacial properties with a cell dielectric material of the capacitor. The TiN also exhibits good mechanical, chemical inertness, and electrical resistance (e.g., low resistance) properties. With decreased size of capacitors, the TiN bottom electrode has decreased in thickness. However, as the thickness decreases, the resistance (Rs) increases exponentially. In addition, cell capacitance (Cs) and dielectric leakage between adjacent DRAM cells are negatively affected as the dimensions and spacing between adjacent capacitors decrease.

### BRIEF DESCRIPTION OF THE DRAWINGS

FIGS. 1 and 2 are simplified, partial cross-sectional views and FIG. 3 is a simplified, partial top-down view of electronic devices including capacitors according to some embodiments of the disclosure;

FIG. 4 is a simplified, partial cross-sectional view and FIG. 5 is a simplified, partial top-down view of electronic devices including capacitors according to additional embodiments of the disclosure;

FIGS. 6-9 are simplified, partial cross-sectional views illustrating a method of forming electronic devices according to embodiments of the disclosure;

FIGS. 10-13 are simplified, partial cross-sectional views illustrating a method of forming electronic devices according to additional embodiments of the disclosure;

FIG. 14 is a functional block diagram of an electronic device in accordance with embodiments of the disclosure; and

FIG. 15 is a schematic block diagram of an electronic system in accordance with embodiments of the disclosure.

### DETAILED DESCRIPTION

A doped titanium nitride (TiN) material is used in a capacitor structure (e.g., a capacitor) of an electronic device (e.g., an apparatus, a microelectronic device) to improve electrical performance. The doped TiN material may be used in the capacitor as a barrier material or may be used as a sacrificial material during fabrication of the capacitor. The doped TiN material may, for example, be oxygen-doped TiN (e.g., TiON, O—TiN). The doped TIN material of the capacitor may facilitate formation of a high-k dielectric material (e.g., a cell dielectric material) of the capacitor without causing a decrease in cell capacitance (Cs) or dielectric leakage degradation. Using the doped TiN material also improves cell resistance. The capacitors according to embodiments of the disclosure may, for example, be DRAM capacitors. However, the capacitors according to embodiments of the disclosure may be used in other electronic devices.

The illustrations presented herein are not actual views of any device or structure, or any component thereof, but are merely idealized representations, which are employed to describe embodiments of the invention.

As used herein, the singular forms following “a,” “an,” and “the” are intended to include the plural forms as well, unless the context clearly indicates otherwise.

As used herein, the term “about” used in reference to a given parameter is inclusive of the stated value and has the meaning dictated by the context (e.g., it includes the degree of error associated with measurement of the given parameter, as well as variations resulting from manufacturing tolerances, etc.).

As used herein, any relational term, such as “first,” “second,” “top,” “bottom,” “upper,” “lower,” “above,” “beneath,” “side,” “upward,” “downward,” etc., is used for clarity and convenience in understanding the disclosure and accompanying drawings, and does not connote or depend on any specific preference or order, except where the context clearly indicates otherwise. For example, these terms may refer to an orientation of elements of any electronic device when utilized in a conventional manner. Furthermore, these terms may refer to an orientation of elements of any electronic device as illustrated in the drawings.

As used herein, the term “may” with respect to a material, structure, feature, or method act indicates that such is contemplated for use in implementation of an embodiment of the disclosure, and such term is used in preference to the more restrictive term “is” so as to avoid any implication that other compatible materials, structures, features, and methods usable in combination therewith should or must be excluded.

As used herein, the term “substantially” in reference to a given parameter, property, or condition means and includes to a degree that one skilled in the art would understand that the given parameter, property, or condition is met with a small degree of variance, such as within acceptable manufacturing tolerances. By way of example, depending on the particular parameter, property, or condition that is substantially met, the parameter, property, or condition may be at least 90.0% met, at least 95.0% met, at least 99.0% met, or even at least 99.9% met.

The doped TiN material may be a material of a bottom electrode of the capacitor or may be one of multiple materials of the bottom electrode. The capacitor may, for example, be a metal-insulator-metal (MIM) capacitor. The bottom electrode of the capacitor may include the doped TiN material and one or more bottom electrode materials, with the doped TiN material adjacent (e.g., directly adjacent) to at least one of the bottom electrode materials. In some embodiments, the doped TiN material is between the bottom electrode material and a high-k dielectric material of the capacitor. In other embodiments, the doped TiN material is between two bottom electrode materials, and one of the bottom electrode materials is adjacent to the high-k dielectric material of the capacitor. Therefore, the bottom electrode material or the doped TiN material may directly contact the high-k dielectric material of the capacitor. The high-k dielectric material may directly contact a top electrode of the capacitor.

The bottom electrode may be formed of two or more electrically conductive materials, such as the doped TiN material and an undoped TiN material as the bottom electrode material. The undoped TiN material and the doped TiN material function, in combination, as the bottom electrode of the capacitor. In some embodiments, the bottom electrode includes two electrically conductive materials. In other embodiments, the bottom electrode includes three electrically conductive materials. However, the bottom electrode may also include greater than three electrically conductive materials.

The doped TiN material of the bottom electrode may be a high work function material that is formulated to recover oxygen vacancies. The doped TiN material may function as an interfacial material (e.g., nucleation material) between materials of the bottom electrode and the high-k dielectric material of the capacitor or as an underlayer for the high-k dielectric material, enabling the high-k dielectric material to be formed more easily. The doped TiN material may also protect an underlying undoped TiN material from structural damage, such as an undesirable increase of the critical dimension (CD), caused by ozone (O₃) or chlorine-based byproducts during subsequent process acts. The doped TiN material lowers the cell resistance and improves structural stability in the electronic device.

The doped TiN material may, for example, be oxygen-doped TiN (e.g., O—TiN, TION), which exhibits an orthorhombic crystal structure. The dopant concentration (e.g., oxygen concentration) in the doped TiN material may be varied depending on desired electrical performance properties of the electronic device. For example, the oxygen content in the doped TiN material may be in the range of from about 10 atomic percent (at. %) to about 60 at. %, such as from about 20 at. % to about 60 at. %, from about 30 at. % to about 55 at. %, from about 35 at. % to about 55 at. %, from about 40 at. % to about 55 at. %, from about 45 at. % to about 55 at. %, from about 35 at. % to about 50 at. %, or from about 40 at. % to about 50 at. %. However, the doped TiN material may include dopants other than oxygen that provide one or more of the above properties. For instance, another dopant may be used that results in a substantially similar crystal structure as oxygen-doped TiN, such as boron-doped TiN or aluminum doped TiN. Silicon-doped TiN is not, however, included (e.g., is excluded) as the material for the doped TiN material since silicon in the bottom electrode of the capacitor may negatively affect performance of the electronic device.

The electronic devices including capacitors according to embodiments of the disclosure exhibit improved dielectric breakdown voltage (BV) and dielectric leakage, and increased device reliability. The doped TiN material of the capacitors also facilitates nucleation of the high-k dielectric material of the capacitor relative to conventional electronic devices in which a high-k dielectric material is formed on an undoped TiN material. In such conventional electronic devices, which lack the bottom electrode including the doped TiN material according to embodiments of the disclosure, oxygen vacancies are formed in the high-k dielectric material due to thermal stresses induced during downstream processing or due to electrical stresses during operation of the electronic device. The lack of the doped TiN material in the conventional electronic devices results in worse dielectric leakage, lower BV, and lower device reliability than in the electronic devices including the doped TiN material in the capacitors according to embodiments of the disclosure.

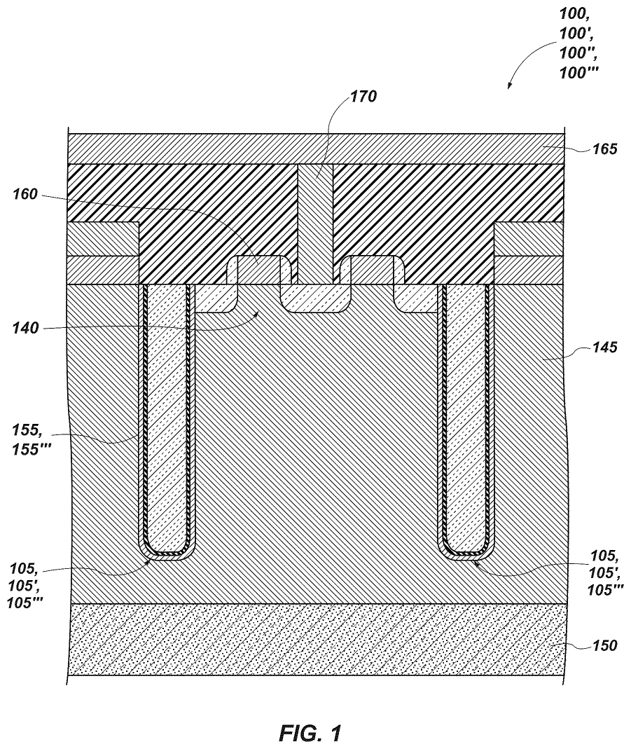

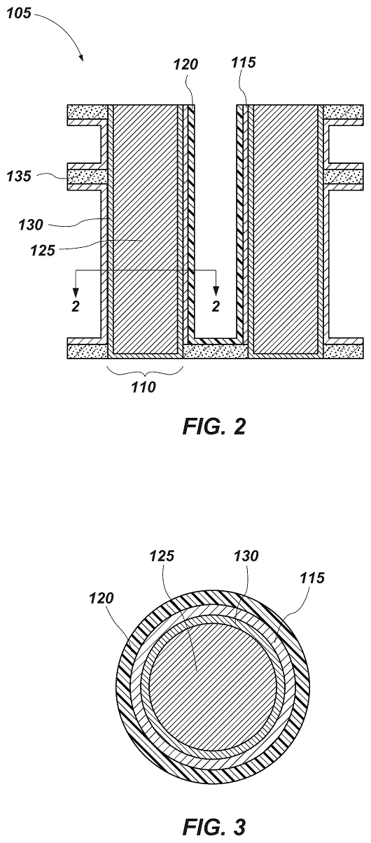

An electronic device 100 that includes a capacitor 105 is shown in FIGS. 1-3. As shown in FIGS. 2 and 3, the capacitor 105 includes a bottom electrode 110, a high-k dielectric material 115, and a top electrode 120, with the high-k dielectric material 115 between the bottom electrode 110 and the top electrode 120. In FIG. 3, the view of the capacitor 105 is taken along the 2-2 line of FIG. 2. The capacitor 105 may, for example, be configured as a DRAM capacitor, such as a MIM capacitor. The top electrode 120 may be adjacent to (e.g., directly adjacent to) the high-k dielectric material 115 and the high-k dielectric material 115 may be adjacent to (e.g., directly adjacent to) the bottom electrode 110. The bottom electrode 110 includes a bottom electrode material 125 and a doped TiN material 130 adjacent to (e.g., directly adjacent to) the bottom electrode material 125. The doped TiN material 130 may, for example, be on sidewalls of the bottom electrode material 125 and adjacent to (e.g., directly adjacent to) a lower surface of the bottom electrode material 125. As shown in FIG. 3, the doped TiN material 130 may substantially surround the bottom electrode material 125, with the bottom electrode material 125 extending (e.g., laterally extending) between opposing sidewalls of the doped TiN material 130. In other words, the bottom electrode material 125 forms a substantially continuous material that extends (e.g., laterally extends) from one sidewall of the doped TiN material 130 to another, opposing sidewall of the doped TiN material 130. The bottom electrode material 125 may be configured as a pillar (e.g., a metal pillar) that is in direct contact with the doped TiN material 130 on three surfaces. An upper surface of the bottom electrode material 125 may be substantially coplanar with an upper surface of the high-k dielectric material 115 and an upper surface of the top electrode 120. The high-k dielectric material 115 directly contacts the top electrode 120 and the doped TiN material 130, and the top electrode 120 directly contacts the high-k dielectric material 115. The bottom electrode material 125 and the doped TiN material 130 may constitute the bottom electrode 110 of the capacitor 105, with a diameter (e.g., a CD) of the bottom electrode 110 substantially equal to a thickness of the bottom electrode material 125 and two times a thickness of the doped TiN material 130. By way of example only, the diameter of the bottom electrode 110 may range from about 20 nm to about 60 nm. Support structures 135 may be positioned laterally adjacent to the capacitor 105. The support structures 135 may be formed of and include a nitride material, such as a dielectric nitride material.

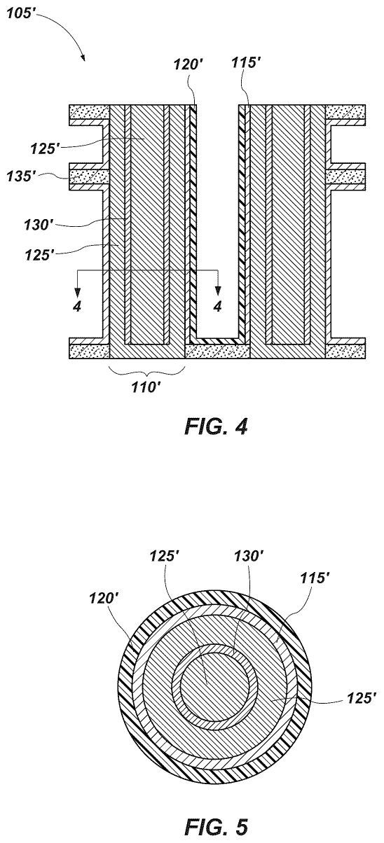

As shown in FIGS. 4 and 5, a capacitor 105′ includes a bottom electrode 110′, a high-k dielectric material 115′, a top electrode 120′, and support structures 135′. The bottom electrode 110′ includes a doped TiN material 130′ between two bottom electrode materials 125′, with opposing surfaces of the doped TiN material 130′ directly contacting respective bottom electrode materials 125′. The doped TiN material 130′ is sandwiched between a first bottom electrode material 125′ and a second bottom electrode material 125′. In FIG. 5, the view of the capacitor 105′ is taken along the 4-4 line of FIG. 4. The doped TiN material 130′ may substantially surround the first electrode material 125′, with the first electrode material 125′ extending between opposing sidewalls of the doped TiN material 130′. The second bottom electrode material 125′ may substantially surround the doped TiN material 130′ and be in direct contact with the high-k dielectric material 115′. The high-k dielectric material 115′ directly contacts the second bottom electrode material 125′ and the top electrode 120′, and the top electrode 120′ directly contacts the high-k dielectric material 115′.

As shown in FIGS. 1-5, the doped TiN material 130, 130′ may form a substantially continuous material surrounding the bottom electrode material 125 or the first bottom electrode material 125′. The doped TiN material 130, 130′ may exhibit a thickness of from a few monolayers to about 90 angstroms (Å), such as from about 0.5 Å to about 70 Å, from about 1.0 Å to about 50 Å, from about 1.0 Å to about 30 Å, from about 3.0 Å to about 20 Å, from about 3.0 Å to about 15 Å, from about 5.0 Å to about 15 Å, or from about 8.0 Å to about 15 Å. The doped TiN material 130, 130′ may be concentrically around the bottom electrode material 125 or around the first bottom electrode material 125′.

The capacitors 105, 105′ differ from each other in the number of electrically conductive materials in the bottom electrode 110, 110′. The one or more bottom electrode materials 125, 125′ of the bottom electrode 110, 110′ may be an undoped TiN material and the doped TiN material 130, 130′ of the bottom electrode 110, 110′ may be oxygen-doped TiN. In some embodiments, the capacitor 105 includes two materials (see FIGS. 2 and 3) as the materials of the bottom electrode 110, such as TION/TiN. In other embodiments, the capacitor 105′ includes three materials (see FIGS. 4 and 5) as the materials of the bottom electrode 110′, such as TiN/TION/TIN or TiSiN/TION/TIN. While the bottom electrodes 110, 110′ shown in FIGS. 2-5 illustrate the bottom electrode materials 125, 125′ and the doped TiN material 130, 130′ as discrete (e.g., distinct) layers, the bottom electrodes 110, 110′ may include material compositions that exhibit a gradient of the dopant in the doped TiN material 130, 130′.

The high-k dielectric material 115 (e.g., the cell dielectric material) of the capacitor 105 may exhibit a dielectric constant greater than about 9. The high-k dielectric material 115 may include, but is not limited to, zirconium oxide (ZrO₂), hafnium oxide (HfO₂), aluminum oxide (AlO₃), lanthanum oxide (La₂O₃), or combinations thereof. The high-k dielectric material 115 may exhibit a thickness of from about 10 angstroms (Å) to about 70 Å.

The top electrode 120 may be formed of one or more electrically conductive materials including, but not limited to, undoped TiN or doped TiN. The electrically conductive material of the top electrode 120 may be the same material composition (e.g., chemical composition) as the electrically conductive materials of the bottom electrode 110, 110′ or may be a different material composition than the electrically conductive material of the bottom electrode 110, 110′.

As shown in FIG. 1, the electronic device 100, 100′, 100″, 100′″ including the capacitors 105, 105′ according to embodiments of the disclosure also includes transistors 140 and pillars of semiconductive material 145 on a base material 150 (e.g., a substrate). The capacitors 105, 105′ are formed in openings 155 within the semiconductive material 145. While FIG. 1 illustrates two capacitor 105, 105′, two transistors 140, and multiple pillars of semiconductive material 145, greater numbers of these features (e.g., components) may be present in the electronic device 100, 100′, 100″, 100′″. The transistors 140 may be arranged in a lateral, a vertical, or any other configuration in other embodiments of the disclosure. The electronic device 100, 100′, 100″, 100′″ may also include access lines 160, sense lines 165, and contacts 170 electrically coupled to the capacitors 105, 105′. The access lines 160, sense lines 165, and contacts 170 of the electronic device 100, 100′, 100″, 100′″ may be formed by conventional techniques. The electronic device 100, 100′, 100″, 100′″ may, for example, be configured as a three dimensional (3D) electronic device, such as a 3D DRAM device. However, the electronic device 100, 100′ may be configured as other memory cell architectures, such as other 3D memory cell architectures.

The base material 150 may be a material or construction upon which additional materials or components of the electronic device 100 are formed. The base material 150 may be an electronic substrate, a semiconductor substrate, a base semiconductor layer on a supporting structure, an electrode, an electronic substrate having one or more materials, layers, structures, or regions formed thereon, or a semiconductor substrate having one or more materials, layers, structures, or regions formed thereon. The base material 150 may include, but is not limited to, a semiconductive material, an insulating material, a conductive material, etc. The base material may be a conventional silicon substrate or other bulk substrate comprising a layer of semiconductive material. The silicon substrate may be monocrystalline silicon (monosilicon), polycrystalline silicon (polysilicon), or amorphous silicon. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The base material 150 may be doped or undoped. When referring to the base material in the following description, previous process acts may have been conducted to form materials or structures in or on the base material 150.

To form the capacitors 105, a stack 600 of one or more materials is formed adjacent to (e.g., over) the base material 150, with capacitor openings 605 (e.g., openings 155) in materials of the stack 600. The materials of the stack 600 may include silicate materials 610 and nitride materials 615 that are selectively etchable relative to one another and relative to the materials of the capacitors 105, 105′. By way of example only, the nitride materials 615 may be a silicon nitride material and the silicate materials 610 may be a tetraalkylorthosilicate material, such as tetraethylorthosilicate (TEOS) or tetramethylorthosilicate (TMOS), borophosphosilicate glass (BPSG), or silicon oxynitride (SiON). The capacitor openings 605 separate the materials of the stack 600 into pillars 620, with the materials of the capacitors 105 to be formed in the capacitor openings 605. The materials of the stack 600 may be formed by conventional deposition techniques and the capacitor openings 605 may be formed by conventional photolithography techniques.

A width W₁ of the capacitor openings 605 may substantially correspond to a diameter of the capacitors 105 formed in the capacitor openings 605, with the capacitors 105 separated from one another by the pillars 620. A height of the stack 600 of materials may substantially correspond to a height of the capacitors 105 to be formed in the capacitor openings 605. The capacitor openings 605 may be etched to a desired depth in the stack 600. The spacing between adjacent capacitor openings 605 may correspond to the desired spacing between adjacent capacitors 105 of the electronic device 100. The pillars 620 may provide support to the materials of the capacitors 105 during fabrication and are also referred to herein as support structures 135. The capacitor openings 605 may be high aspect ratio (HAR) openings defined by sidewalls of the stack 600 of materials. By way of example only, the capacitor openings 605 may exhibit an aspect ratio of greater than or equal to about 20:1.

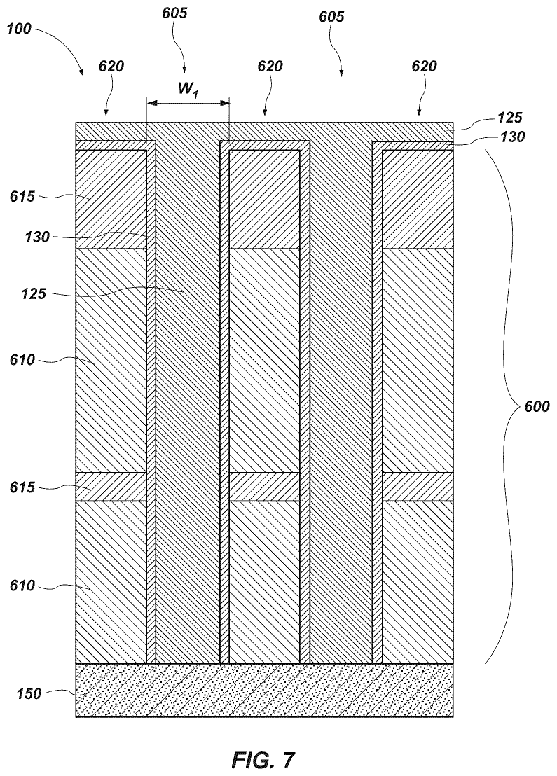

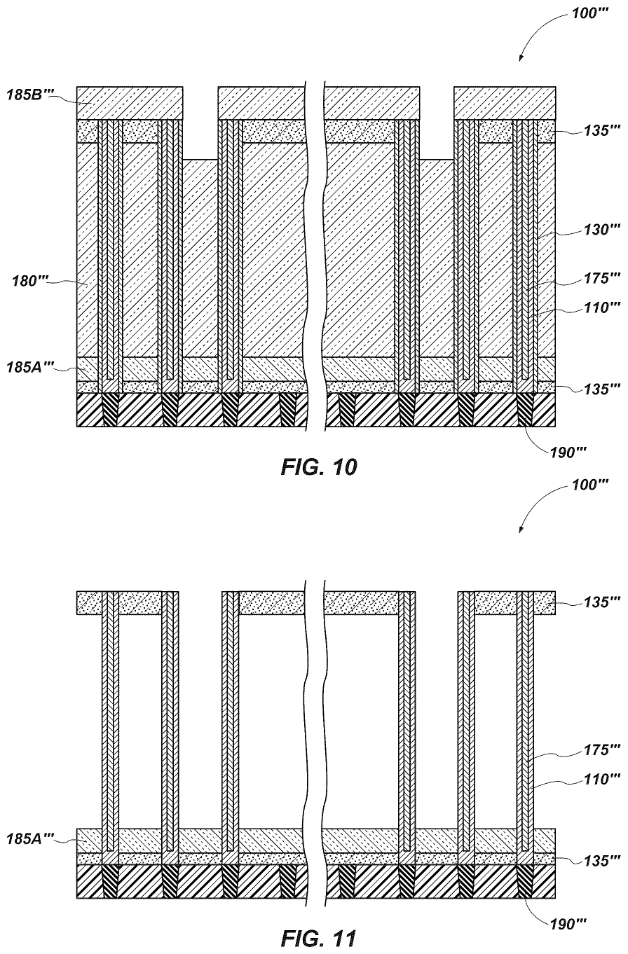

The doped TiN material 130 and the one or more bottom electrode material(s) 125 of the bottom electrode 110 may be formed in the capacitor openings 605 as shown in FIG. 7. The doped TiN material 130 may be formed on sidewalls of the stack 600 and over an uppermost material of the stack 600. The bottom electrode material 125 may be formed on sidewalls of the doped TiN material 130, on an upper surface of the base material 150, and on an upper surface of the doped TiN material 130. The doped TiN material 130 and the bottom electrode material 125 may substantially completely fill the capacitor openings 605. Alternatively, the doped TiN material 130 and the bottom electrode material 125 may partially fill (not shown in FIG. 7) the capacitor openings 605, with a portion of the capacitor openings 605 remaining unfilled. The remaining volume of the capacitor openings 605 may subsequently be filled with a fill material (not shown in FIG. 7), such as a silicon fill material. Therefore, the capacitors 105 may include the bottom electrode material 125 extending (e.g., laterally extending) between sidewalls of the doped TiN material 130 or may include the bottom electrode material 125 surrounding the fill material (see FIGS. 10-13) and the doped TiN material 130 surrounding the bottom electrode material 125. To form the bottom electrode 110′, in which multiple bottom electrode materials 125 are present, the additional bottom electrode materials 125 are formed before or after forming the doped TiN material 130 in the capacitor openings 605. If the bottom electrode 110′ includes multiple bottom electrode materials 125′, a first bottom electrode material 125′ is formed as described above, the doped TiN material 130′ is formed on the first bottom electrode material 125′, and a second bottom electrode material 125′ is formed on the doped TiN material 130′.

The doped TiN material 130 and the bottom electrode material 125 may be conformally formed in the capacitor openings 605, such as by a conformal deposition process. The conformal deposition process may include, but is not limited to, chemical vapor deposition (CVD) or atomic layer deposition (ALD). The doped TiN material 130 and the bottom electrode material 125 may be formed in a single deposition chamber, in multiple deposition chambers, or in a batch furnace. To form the doped TiN material 130, precursor gases, such as a titanium precursor gas, a nitrogen precursor gas, and a dopant precursor gas, are sequentially introduced into the capacitor openings 605. A desired material composition (e.g., a chemical composition) of the doped TiN material 130 may be formed by adjusting deposition parameters, such as flow rates of the precursor gases and a process temperature. By adjusting the relative amounts of the precursor gases, such as by adjusting the flow rates, the chemical composition of the doped TiN material 130 may be tailored. If, for example, the dopant in the doped TiN material 130 is oxygen, the oxygen content of the doped TiN material 130 may be tailored by adjusting (e.g., increasing, decreasing) the flow rate of an oxygen precursor gas in the deposition chamber relative to the flow rates of titanium precursor gas and nitrogen precursor gas. To increase the oxygen content of the doped TiN material 130, the flow rate of the oxygen precursor gas relative to the flow rates of the titanium precursor gas and the nitrogen precursor gas may be increased. Alternatively, the number of oxygen ALD loop cycles relative to the number of TIN ALD loop cycles may be increased. Similarly, to decrease the oxygen content of the doped TIN material 130, the flow rate of the oxygen precursor gas relative to the flow rates of the titanium precursor gas and the nitrogen precursor gas may be decreased. Alternatively, the number of oxygen ALD loop cycles relative to the number of TIN ALD loop cycles may be decreased. The chemical composition of the doped TiN material 130 may also be tailored by controlling the temperature at which the doped TiN material 130 is formed. By way of example only, the doped TiN material 130 may be formed at a temperature of from about 350° C. to about 550° C. The flowrates of the precursor gases, the number of oxygen/TIN ALD loop cycles, and/or the process temperature may be selected depending on the desired chemical composition of the doped TiN material 130.

To form the bottom electrode material 125, precursor gases, such as the titanium precursor gas and the nitrogen precursor gas, are sequentially introduced into the capacitor openings 605. The bottom electrode material 125 may be formed by adjusting deposition parameters, such as the flow rates of the precursor gases and the process temperature. By way of example only, the bottom electrode material 125 may be formed at a temperature of from about 350° C. to about 550° C.

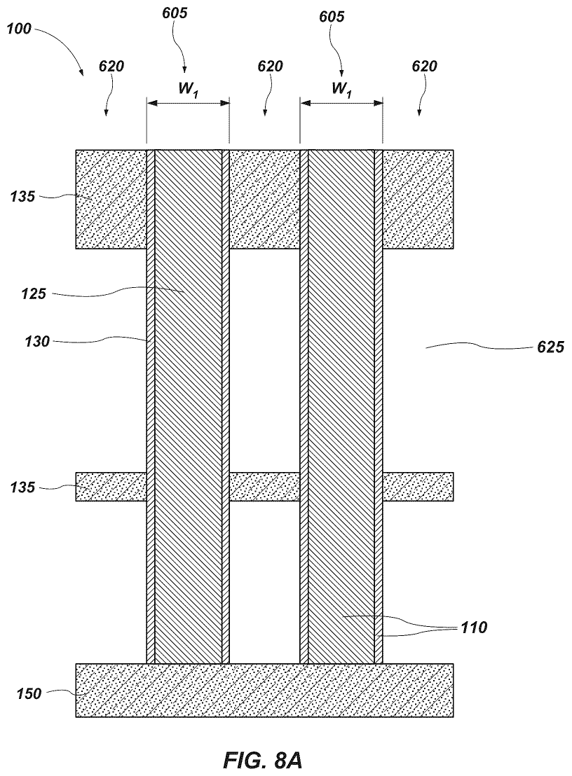

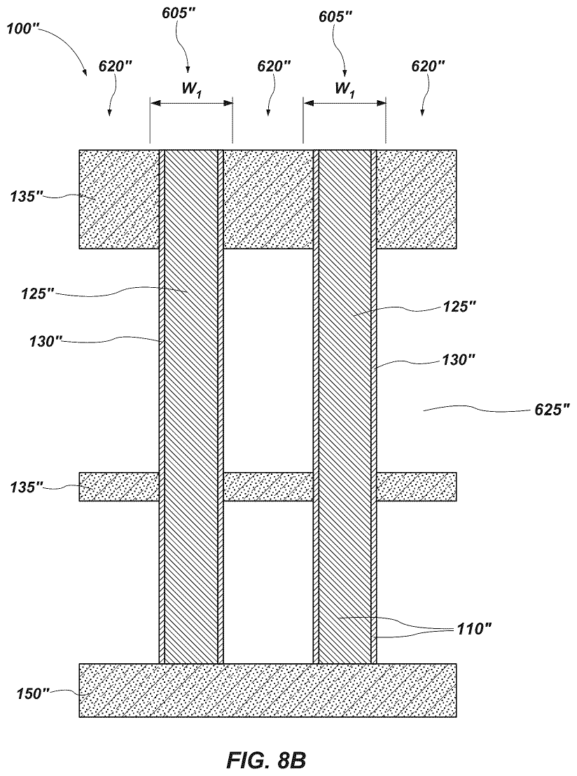

As shown in FIGS. 8A and 8B, the bottom electrode material 125, 125″ and the doped TiN material 130, 130″ extending over the uppermost material of the stack 600 may be removed to form the electronic devices 100, 100″. The portions of the bottom electrode material 125, 125″ and the doped TiN material 130, 130″ may be removed by a chemical mechanical planarization (CMP) process. Therefore, upper surfaces of the bottom electrode material 125, 125″ and the doped TiN material 130, 130″ in the capacitor openings 605, 605″ may be substantially coplanar with the uppermost material of the stack 600. The bottom electrode material 125, 125″ and the doped TiN material 130, 130″ form the bottom electrode 110, 110″, which has a diameter substantially equal to the width W₁ of the capacitor openings 605, 605″. The silicate materials 610 of the stack 600 may be selectively removed relative to the nitride materials 615 and exposed materials of the bottom electrode 110, 110″. The silicate materials 610 may be removed by conventional techniques. The nitride materials 615, 615″ remain and function as the support structures 135, 135″, which are vertically separated from one another by spaces 625.

As shown in FIG. 8A, the thickness of the doped TiN material 130 may remain substantially equal to the thickness as initially formed before forming the top electrode 120 or additional bottom electrode materials 125. As shown in FIG. 8B, a portion of the doped TiN material 130 exposed by the spaces 625 may be removed depending on a desired thickness of the doped TiN material 130″ in the bottom electrode 110″. The doped TiN material 130″ may, therefore, be thinner (e.g., have a smaller thickness) than the thickness of the doped TiN material 130 as initially formed. The bottom electrode material 125″ and the doped TiN material 130″ constitute the bottom electrode 110″, which has a diameter less than the width W₁ of the capacitor openings 605″. Therefore, the bottom electrode 110″ may be formed at a smaller diameter without forming the capacitor openings 605″ at a smaller CD. The diameter of the bottom electrode 110″ may correspond to the width of the thinned doped TiN material 130″ and the width of the bottom electrode material 125″ as formed. If the bottom electrode 110″ is to include multiple bottom electrode materials 125″, the bottom electrode materials 125″ may be formed on sidewalls of the thinned doped TiN material 130″. For instance, the first bottom electrode material 125′ is formed as described above and the second bottom electrode material 125′ is formed over the doped TiN material 130″.

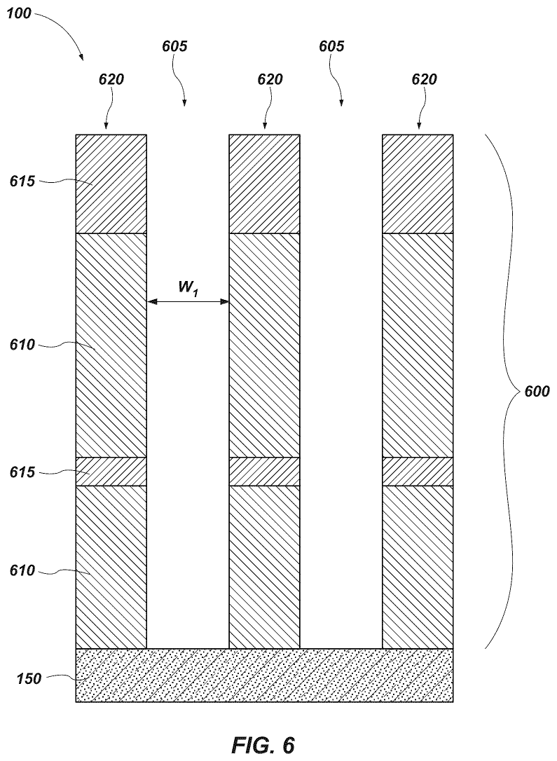

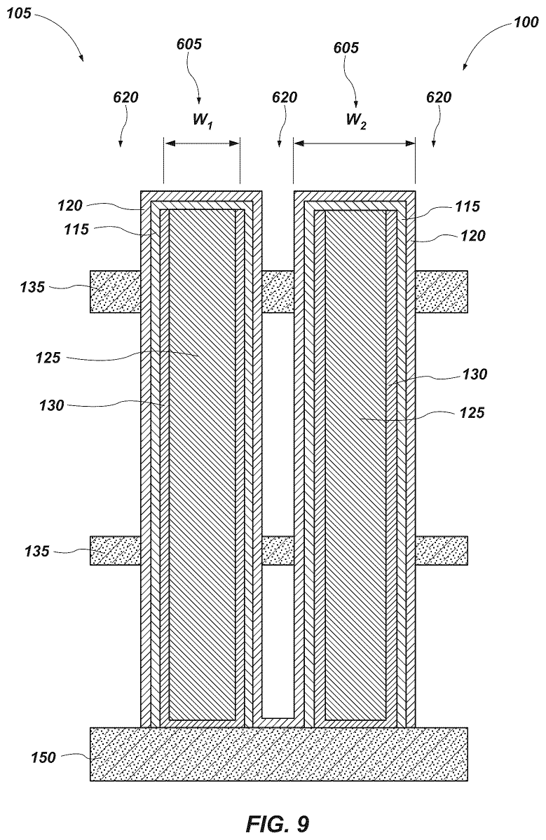

The high-k dielectric material 115 is formed on the bottom electrode 110 and the top electrode 120 is formed on the high-k dielectric material 115, as shown in FIG. 9. While FIGS. 6-9 show the formation of capacitors 105, the capacitors 105′ may be formed similarly, with the multiple bottom electrode materials 125′ and doped TiN material 130′ of the capacitors 105′ formed in the capacitor openings 605. Capacitors 105, 105′ having the thinned doped TiN material 130″ may also be formed similarly. The high-k dielectric material 115 and the top electrode 120 may be formed by conventional techniques, such as by a conformal deposition technique including, but not limited to, ALD. The high-k dielectric material 115 and the top electrode 120 are individually formed to a thickness that provides desired electrical performance of the electronic device 100. Portions of the high-k dielectric material 115 and the top electrode 120 may be removed to form the capacitors 105, 105′ shown in FIGS. 2-5. The high-k dielectric material 115 and the top electrode 120 may be removed by, for example, a CMP process.

The doped TiN material may, alternatively, be used as a sacrificial material during the formation of an electronic device 100′″ as shown in FIGS. 10-13. The doped TiN material may be referred to herein as a sacrificial doped TiN material 130′″. By forming and removing the sacrificial doped TIN material 130′″ during the formation of capacitors 105′″ of the electronic device 100′″, the diameter of a resulting bottom electrode 110′″ may be decreased relative to an electronic device in which the doped TiN material 130, 130′, 130″ remains. The diameter of the bottom electrode 110′″ may, therefore, be decreased without forming capacitor openings 605′″ at a smaller CD. By reducing the diameter of the bottom electrode 110″, an increased density of capacitors 105′″ may be formed in a given footprint. An as-formed thickness of the sacrificial doped TiN material 130′″ may correspond to the reduction in diameter of the bottom electrode 110′″. In addition, using the sacrificial doped TiN material 130′″ produces an improved interface between the bottom electrode 110′″ and adjacent materials of the capacitors 105′″. The sacrificial doped TiN material 130′″ may be selectively removed by a wet etch process that does not substantially remove other exposed materials of the capacitors 105′″. The sacrificial doped TiN material 130′″ may be used as a sacrificial material during the fabrication of the capacitors 105′″ to produce an electronic device 100′″ in which a smaller diameter bottom electrode 110′″ is desired, such as in a 3D DRAM device or other 3D memory cell architecture.

An initial process stage of fabrication of an electronic device 100′″ is shown in FIG. 10. The electronic device 100′″ may include capacitors 105′″ according to additional embodiments of the disclosure, which are similar to the capacitors 105, 105′, 105″ (see FIGS. 2-5 and 9) except having a small diameter bottom electrode 110′″. Similar to the capacitors 105, 105′, 105″ and processes illustrated in FIGS. 1-9 and described above, the electronic device 100′″ includes one or more materials of the bottom electrode 110′″ formed in capacitor openings 605′″ (e.g., openings 155′″) The capacitor openings 605′″ may be HAR openings. The materials of the bottom electrode 110′″ are formed on a base material (not shown in FIG. 10), similar to the base material 150 of FIGS. 1-9. For convenience and simplicity, the bottom electrode 110′″ is shown as a single material in FIGS. 10-13. However, the bottom electrode 110′″ may include multiple materials. The electronic device 100′″ also includes a fill material 175′″ and the sacrificial doped TiN material 130′″ in the capacitor openings 605′″, with the materials of the bottom electrode 110′″ on sidewalls of the fill material 175′″ and the sacrificial doped TiN material 130′″ on sidewalls of the bottom electrode 110″. The sacrificial doped TiN material 130′″ may be an oxygen-doped TiN material, as described above for the doped TiN material 130, 130′, 130″ and illustrated in FIGS. 1-9. The fill material 175′″, the bottom electrode 110″, and the sacrificial doped TiN material 130′″ may substantially fill the capacitor openings 605′″ A sacrificial dielectric material 180′″ is present adjacent to (e.g., laterally adjacent to) the bottom electrode 110″, with the fill material 175′″ and the bottom electrode 110′″ extending (e.g., extending vertically) through the sacrificial dielectric material 180′″. The sacrificial dielectric material 180′″ may include a single material or one or more materials, similar to the stack 600 of FIGS. 6 and 7. Support structures 135′″ may also be adjacent to the bottom electrode 110′″. Additional dielectric materials 185A′″. 185B′″ are present around upper and lower portions of the bottom electrode 110″ and may provide one or more of support, electrical isolation, or other functions to the electronic device 100′″ during fabrication and during use. One or more of the sacrificial doped TiN material 130′″, the sacrificial dielectric material 180′″, and the additional dielectric materials 185A′″, 185B′″ may be selectively etchable relative to the bottom electrode 110″. The electronic device 100′″ also includes contacts 190′″ adjacent to (e.g., vertically adjacent to) the bottom electrode 110″.

The materials and components shown in the initial process stage of FIG. 10 may be formed by conventional techniques. For instance, the capacitor openings 605′″ may be formed in the sacrificial dielectric material 180′″ as previously described, the sacrificial doped TiN material 130′″ may be formed on sidewalls of the sacrificial dielectric material 180′″ and within the capacitor openings 605′″, the material(s) of the bottom electrode 110′″ may be formed on sidewalls of the sacrificial doped TiN material 130′″ and with the capacitor openings 605′″, and the fill material 175′″ may be formed on sidewalls of the bottom electrode 110″ and within the capacitor openings 605′″.

A thickness at which the sacrificial doped TIN material 130′″ is formed may depend on a desired reduction in diameter of the bottom electrode 110′″. By way of example only, the sacrificial doped TiN material 130′″ may be formed at a thickness of from a few monolayers to about 90 angstroms (Å), such as from about 0.5 Å to about 70 Å, from about 1.0 Å to about 50 Å, from about 1.0 Å to about 30 Å, from about 3.0 Å to about 20 Å, from about 3.0 Å to about 15 Å, from about 5.0 Å to about 15 Å, or from about 8.0 Å to about 15 Å.

As shown in FIG. 11, the sacrificial doped TIN material 130′″, the sacrificial dielectric material 180′″, and one or more of the dielectric materials 185A′″, 185B′″ may be selectively removed without removing the bottom electrode 110″. For instance, each of the sacrificial doped TiN material 130′″, the sacrificial dielectric material 180′″, and the dielectric materials 185A′″, 185B′″ may be removed by a separate etch process. Alternatively, the sacrificial dielectric material 180′″ and the dielectric materials 185A′″, 185B′″ may be removed by one or more etch processes followed by removal of the sacrificial doped TiN material 130′″, or the sacrificial doped TiN material 130′″, the sacrificial dielectric material 180′″, and the dielectric materials 185A′″, 185B′″ may be removed by a single etch process. However, and as shown in FIG. 11, the dielectric materials 185A′″ may remain to provide support to the bottom electrode 110′″ and fill material 175′″, along with the support structures 135′″. In some embodiments, the sacrificial doped TiN material 130′″, the sacrificial dielectric material 180′″, and the dielectric materials 185B′″ are removed substantially simultaneously. The sacrificial doped TiN material 130′″ is substantially completely removed, such as by using a solution of hydrogen fluoride. The selective removal of the sacrificial doped TiN material 130′″ occurs without substantially removing the materials of the bottom electrode 110′″. Therefore, a smaller diameter bottom electrode 110′″ may be formed within the capacitor openings 60S′″ without having to initially form smaller capacitor openings 605′″ and with the reduction in diameter corresponding to the thickness of the sacrificial doped TIN material 130′″. Since the sacrificial doped TiN material 130′″ is formed in the capacitor openings 605′″ before forming the bottom electrode 110′″ and the fill material 175′″, the sacrificial doped TiN material 130′″ reduces a volume of space remaining in the capacitor openings 605′″ for the bottom electrode 110′″ and fill material 175′″. Therefore, the bottom electrode 110′″ and fill material 175′″ occupy a smaller volume of the capacitor openings 605′″ and have a reduced diameter.

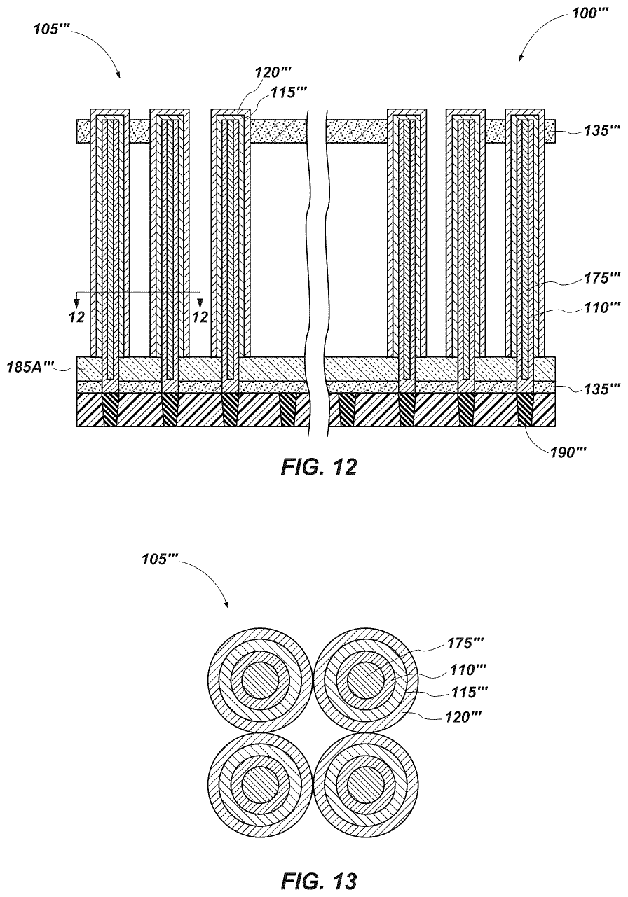

A high-k dielectric material 115′″ and top electrode 120′″ may be formed on sidewalls of the bottom electrode 110′″ to form the capacitors 10S′″, as shown in FIGS. 12 and 13. The high-k dielectric material 115′″ may be one of the materials described above and the top electrode 120′″ may include one or more conductive materials as described above. For convenience and simplicity, the top electrode 120′″ is shown as a single material in FIG. 12.

The electronic device 100′″ including the capacitors 105′″ exhibits reduced shorting compared to conventional electronic devices since adjacent capacitors 105′″ are further separated from one another. By removing the sacrificial doped TiN material 130′″ before forming the remaining materials of the capacitors 105′″, the spacing between adjacent capacitors 105′″ is increased and the materials of the capacitors 105′″ do not contact one another, as shown in FIG. 13. A desired spacing between adjacent capacitors 105′″ may be tailored for different electronic devices 100′″ by adjusting the thickness of the sacrificial doped TiN material 130′″. The capacitors 10S′″ also exhibits an interface between the bottom electrode 110′″ and adjacent materials of the capacitors 105′″ that is substantially free of silicon. More specifically, the interface between the bottom electrode 110′″ and the high-k dielectric material 115′″ may be substantially free of silicon. Since no silicon is present in the sacrificial doped TiN material 130′″, no silicon diffuses into the bottom electrode 110′″ during fabrication of the electronic device 100′″. Therefore, performance of the electronic device 100′″ formed according to embodiments of the disclosure is improved.

While FIGS. 1-13 illustrate electronic devices 100, 100′, 100″, 100′″ in a DRAM memory cell architecture, the capacitors 105, 105′, 105″, 105′″ may be used in other RAM, flash (e.g., NAND or NOR), or 3D memory cell architectures. In addition, the transistors 140 may be arranged in a lateral, a vertical, or any other configuration in other embodiments of the disclosure. The capacitors 105, 105′, 105″, 105′″ according to embodiments of the disclosure may be configured to store a particular charge corresponding to a data value.

The dimensions of capacitors 105, 105′, 105″, 105′″ of the electronic devices 100, 100′, 100″, 100′″ may be decreased relative to conventional electronic devices while the spacing between adjacent capacitors 105, 105′, 105″, 105′″ is increased or remains substantially the same. By using the doped TiN material 130, 130′, 130″ or the sacrificial doped TiN material 130″ according to embodiments of the disclosure, the cell capacitance (Cs) of the capacitors 105, 105′, 105″, 105′″ of the electronic devices 100, 100′, 100″, 100′″ may be increased while less dielectric leakage occurs between adjacent DRAM cells. The doped TiN material 130, 130′, 130″ may also facilitate the formation of the high-k dielectric material 115, 115′, 115′″ without causing a decrease in Cs.

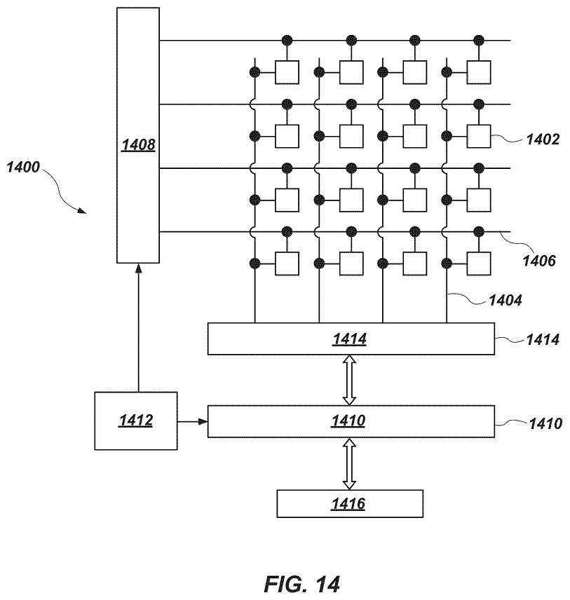

The electronic devices 100, 100′, 100″, 100′″ may be subjected to additional processing acts, as desired, to form an electronic device 1400 (e.g., a microelectronic device, a memory device) including the electronic devices 100, 100′, 100″, 100′″, as shown in FIG. 14. Such additional processing may employ conventional processes and conventional processing equipment. The electronic device 1400 may include, for example, embodiments of the electronic devices 100, 100′, 100″, 100′″ previously described. As shown in FIG. 14, the electronic device 1400 may include memory cells 1402, data lines 1404 (e.g., digit lines, bit lines), access lines 1406 (e.g., word lines), a row decoder 1408, a column decoder 1410, a memory controller 1412, a sense device 1414, and an input/output device 1416.

The memory cells 1402 of the electronic device 1400 are programmable to at least two different logic states (e.g., logic 0 and logic 1). Each memory cell 1402 may individually include a capacitor and transistor (not shown). The capacitor stores a charge representative of the programmable logic state (e.g., a charged capacitor may represent a first logic state, such as a logic 1; and an uncharged capacitor may represent a second logic state, such as a logic 0) of the memory cell 1402. The transistor grants access to the capacitor responsive to application (e.g., by way of one of the access lines 1406) of a minimum threshold voltage to a semiconductive channel thereof for operations (e.g., reading, writing, rewriting) on the capacitor.

The data lines 1404 are connected to the capacitors of the memory cells 1402 by way of the transistors (corresponding to transistors 140 in FIG. 1) of the memory cells 1402. The access lines 1406 extend perpendicular to the data lines 1404, and are connected (e.g., electrically connected) to gates of the transistors of the memory cells 1402. Operations may be performed on the memory cells 1402 by activating appropriate data lines 1404 and access lines 1406. Activating a data line 1404 or an access line 1406 may include applying a voltage potential to the data line 1404 or the access line 1406. Each column of memory cells 1402 may individually be connected to one of the data lines 1404, and each row of the memory cells 1402 may individually be connected to one of the access lines 1406. Individual memory cells 1402 may be addressed and accessed through intersections of the data lines 1404 and the access lines 1406.

The memory controller 1412 may control the operations of the memory cells 1402 through various components, including the row decoder 1408, the column decoder 1410, and the sense device 1414. The memory controller 1412 may generate row address signals that are directed to the row decoder 1408 to activate (e.g., apply a voltage potential to) predetermined access lines 1406, and may generate column address signals that are directed to the column decoder 1410 to activate (e.g., apply a voltage potential to) predetermined data lines 1404. The memory controller 1412 may also generate and control various voltage potentials employed during the operation of the electronic device 1400. The amplitude, shape, and/or duration of an applied voltage may be adjusted (e.g., varied), and may be different for various operations of the electronic device 1400.

During use and operation of the electronic device 1400, after being accessed, a memory cell 1402 may be read (e.g., sensed) by the sense device 1414. The sense device 1414 may compare a signal (e.g., a voltage) of an appropriate data line 1404 to a reference signal in order to determine the logic state of the memory cell 1402. If, for example, the data line 1404 has a relatively higher voltage than the reference voltage, the sense device 1414 may determine that the stored logic state of the memory cell 1402 is a logic 1, and vice versa. The sense device 1414 may include transistors and amplifiers to detect and amplify a difference in the signals. The detected logic state of a memory cell 1402 may be output through the column decoder 1410 to the input/output device 1416. In addition, a memory cell 1402 may be set (e.g., written) by similarly activating an appropriate access line 1406 and an appropriate data line 1404 of the electronic device 1400. By controlling the data line 1404 while the access line 1406 is activated, the memory cell 1402 may be set (e.g., a logic value may be stored in the memory cell 1402). The column decoder 1410 may accept data from the input/output device 1416 to be written to the memory cells 1402. Furthermore, a memory cell 1402 may also be refreshed (e.g., recharged) by reading the memory cell 1402. The read operation will place the contents of the memory cell 1402 on the appropriate data line 1404, which is then pulled up to full level (e.g., full charge or discharge) by the sense device 1414. When the access line 1406 associated with the memory cell 1402 is deactivated, all of memory cells 1402 in the row associated with the access line 1406 are restored to full charge or discharge.

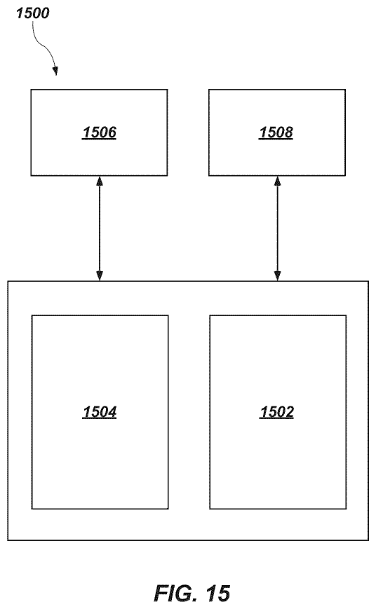

The electronic devices 100, 100′, 100″, 100′″ according to embodiments of the disclosure may be used in embodiments of electronic systems of the disclosure. For example, FIG. 15 is a block diagram of an illustrative electronic system 1500 according to embodiments of disclosure. The electronic system 1500 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The electronic system 1500 includes at least one electronic device 1400. The electronic device 1400 may comprise, for example, an embodiment of one or more of the electronic devices 100, 100′, 100″, 100′″ previously described herein. The electronic system 1500 may further include at least one electronic signal processor device 1504 (often referred to as a “microprocessor”). The electronic signal processor device 1504 may, optionally, include an embodiment of the electronic devices 100, 100′, 100″, 100′″ previously described herein. The electronic system 1500 may further include one or more input devices 1506 for inputting information into the electronic system 1500 by a user, such as, for example, a mouse or other pointing device, a keyboard, a touchpad, a button, or a control panel. The electronic system 1500 may further include one or more output devices 1508 for outputting information (e.g., visual or audio output) to a user such as, for example, a monitor, a display, a printer, an audio output jack, a speaker, etc. In some embodiments, the input device 1506 and the output device 1508 may comprise a single touchscreen device that may be used both to input information to the electronic system 1500 and to output visual information to a user. The input device 1506 and the output device 1508 may communicate electrically with one or more of the electronic device 1502 and the electronic signal processor device 1504.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternate useful combinations of the elements described, will become apparent to those skilled in the art from the description. Such modifications and embodiments also fall within the scope of the appended claims and equivalents.

What is claimed is:

1. An apparatus, comprising:
one or more capacitors comprising:
a bottom electrode comprising an oxygen-doped titanium nitride material and one or more undoped titanium nitride materials, the oxygen-doped titanium nitride material on sidewalls of the one or more undoped titanium nitride materials and the one or more undoped titanium nitride materials extending between sidewalls of the oxygen-doped titanium nitride material;
a high-k dielectric material contacting the oxygen-doped titanium nitride material of the bottom electrode; and
a top electrode adjacent to the high-k dielectric material.

2. The apparatus of claim 1, wherein the oxygen-doped titanium nitride material comprises from about 20 atomic percent (at. %) to about 60 at. % oxygen.

3. The apparatus of claim 1, wherein the oxygen-doped titanium nitride material directly contacts the one or more undoped titanium nitride materials and the high-k dielectric material.

4. The apparatus of claim 1, wherein the oxygen-doped titanium nitride material is between and directly contacts two undoped titanium nitride materials.

5. The apparatus of claim 1, wherein the bottom electrode consists of the oxygen-doped titanium nitride material and the undoped titanium nitride material, the oxygen-doped titanium nitride material between the high-k dielectric material and the undoped titanium nitride material.

6. The apparatus of claim 1, wherein the bottom electrode consists of the oxygen-doped titanium nitride material and two undoped titanium nitride materials, the oxygen-doped titanium nitride material between the two undoped titanium nitride materials.

7. An electronic device, comprising:
one or more capacitors comprising:
a bottom electrode comprising an oxygen-doped titanium nitride material surrounding an undoped titanium nitride material, the oxygen-doped titanium nitride material comprising from about 20 atomic percent (at. %) to about 60 at. % oxygen and the undoped titanium nitride material directly contacting the oxygen-doped titanium nitride material;
a high-k dielectric material adjacent to the oxygen-doped titanium nitride material; and
a top electrode adjacent to the high-k dielectric material.

8. The electronic device of claim 7, wherein the oxygen-doped titanium nitride material exhibits a thickness of from about 0.5 Å to about 70 Å.

9. The electronic device of claim 7, wherein an interface between the bottom electrode and the high-k dielectric material is substantially free of silicon.

10. The electronic device of claim 7, wherein the high-k dielectric material directly contacts the oxygen-doped titanium nitride material.

11. The electronic device of claim 7, wherein the oxygen-doped titanium nitride material comprises from about 35 at. % to about 50 at. % oxygen.

12. A method of forming an electronic device, comprising:
forming an oxygen-doped titanium nitride material in capacitor openings in a stack of one or more dielectric materials;
forming one or more bottom electrode materials in the capacitor openings and adjacent to the oxygen-doped titanium nitride material;
removing one or more dielectric materials of the stack to expose the oxygen-doped titanium nitride material;
forming a high-k dielectric material on the oxygen-doped titanium nitride material; and
forming a top electrode on the high-k dielectric material.

13. The method of claim 12, wherein forming an oxygen-doped titanium nitride material in capacitor openings in a stack of one or more dielectric materials comprises forming the oxygen-doped titanium nitride material on sidewalls of the stack.

14. The method of claim 12, wherein forming an oxygen-doped titanium nitride material in capacitor openings in a stack comprises forming the oxygen-doped titanium nitride material in capacitor openings comprising an aspect ratio of greater than or equal to about 20:1.

15. The method of claim 12, wherein forming one or more bottom electrode materials in the capacitor openings and adjacent to the oxygen-doped titanium nitride material comprises forming an undoped titanium nitride material directly contacting the oxygen-doped titanium nitride material.

16. The method of claim 12, wherein forming one or more bottom electrode materials in the capacitor openings and adjacent to the oxygen-doped titanium nitride material comprises forming an undoped titanium nitride material directly contacting and on opposing surfaces of the oxygen-doped titanium nitride material.

17. The method of claim 12, wherein removing one or more dielectric materials of the stack to expose the oxygen-doped titanium nitride material comprises selectively removing one of the dielectric materials while another of the dielectric material remains.

18. The method of claim 17, wherein selectively removing one of the dielectric materials while another of the dielectric material remains comprises forming support structures comprising the another of the dielectric materials.

19. The method of claim 12, further comprising removing a portion of the oxygen-doped titanium nitride material before forming the high-k dielectric material and the top electrode.

20. The method of claim 12, further comprising substantially removing the oxygen-doped titanium nitride material before forming the high-k dielectric material and the top electrode.
